(19) United States
(12) Patent Application Publication
(10) Pub. No.: US 2026/0344155 A1
(43) Pub. Date: Oct. 29, 2026

(54) Display Device

(71) Applicant: LG Display Co., Ltd., Seoul (KR)

(72) Inventors: Dae-Il Kang, Gimpo-shi (KR); Soojin Kim, Incheon (KR)

(21) Appl. No.: 19/577,240

(22) Filed: Mar. 24, 2026

(30) Foreign Application Priority Data
Apr. 29, 2025 (KR) 10-2025-0056642

(51) Int. Cl. H10H 29/80; H10H 29/41; H10H 29/49; H10H 29/855

(52) U.S. Cl. CPC H10H 29/8325; H10H 29/41; H10H 29/49; H10H 29/8321; H10H 29/8552

(57) ABSTRACT

A display device according to an exemplary embodiment of the present disclosure includes a substrate in which a plurality of sub pixels each including a repair site is defined, a reflective electrode disposed in each of the plurality of sub pixels, a repair electrode disposed at the repair site and electrically connected to the reflective electrode, a light emitting element disposed on the reflective electrode, a first insulating layer disposed on the reflective electrode, and a second insulating layer disposed on the repair electrode. Accordingly, each of the plurality of sub pixels includes a repair site for repair.

### CROSS-REFERENCE TO RELATED APPLICATIONS

This application claims the priority of Republic of Korea Patent Application No.10-2025-0056642 filed on Apr.29, 2025, in the Ministry of Intellectual Property of the Republic of Korea, the disclosure of which is incorporated herein by reference.

### FIELD

The present disclosure relates to a display device, and more particularly, to a display device using a light emitting diode (LED).

### BACKGROUND

Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, recently, a display device including an LED is attracting attention as a next-generation display device. Since the LED is made of an inorganic material rather than an organic material, reliability is excellent, and a lifespan thereof is longer than that of a liquid crystal display device or an organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to provide a display device capable of repairing a sub pixel.

Another object to be achieved by the present disclosure is to provide a display device in which a defect of a sub pixel is minimized.

Still another object to be achieved by the present disclosure is to provide a display device in which a light emitting element is directly connected to an electrode.

Still another object to be achieved by the present disclosure is to provide a display device in which a light emitting element is immersed in an insulating layer to be connected to an electrode.

Still another object to be achieved by the present disclosure is to provide a display device in which light extraction efficiency of a light emitting element is improved.

Still another object to be achieved by the present disclosure is to provide a display device which easily fixes a light emitting element transferred to a display panel.

Objects of the present disclosure are not limited to the above-mentioned objects, and other objects, which are not mentioned above, can be clearly understood by those skilled in the art from the following descriptions.

A display device according to an exemplary embodiment of the present disclosure includes a substrate in which a plurality of sub pixels each including a repair site is defined, a reflective electrode disposed in each of the plurality of sub pixels, a repair electrode disposed at the repair site and electrically connected to the reflective electrode, a light emitting element disposed on the reflective electrode, a first insulating layer disposed on the reflective electrode and the repair electrode and in contact with at least a part of the light emitting element, and a second insulating layer disposed on the repair electrode in at least some of the plurality of sub pixels, the first insulating layer is opened at the repair site to expose the repair electrode from the first insulating layer, and the second insulating layer is in contact with the repair electrode. Accordingly, each of the plurality of sub pixels includes a repair site for repair, thereby minimizing defective sub pixels.

A display device according to another exemplary embodiment of the present disclosure includes: a substrate in which a plurality of sub pixels are defined, wherein at least a part of the sub pixels include a light emitting element and an additional light emitting element, wherein each of the at least a part of the sub pixels includes: a reflective electrode disposed on the substrate; a repair electrode electrically connected to the reflective electrode; the light emitting element disposed on the reflective electrode; the additional light emitting element disposed on the repair electrode; a first insulating layer disposed on the reflective electrode; and a second insulating layer disposed on the first insulating layer, and wherein the second insulating layer is in contact with the repair electrode.

Other detailed matters of the embodiments are included in the detailed description and the drawings.

According to the present disclosure, a repair site is formed in a sub pixel, so that a defective sub pixel may be easily repaired.

According to the present disclosure, the light emitting element may be easily moved toward the reflective electrode in a soldering process for connecting the light emitting element and the reflective electrode.

According to the present disclosure, during the soldering process, the light emitting element is immersed in the insulating layer to easily connect the light emitting element and the reflective electrode under the insulating layer.

According to the present disclosure, it is possible to improve light extraction efficiency by forming a reflective electrode having a cup structure.

According to the present disclosure, a soldering process may be performed while the light emitting element is fixed.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram of a display device according to an exemplary embodiment of the present disclosure.

FIG. 2 is a partial cross-sectional view of a display device according to an exemplary embodiment of the present disclosure.

FIGS. 3 and 4 are cross-sectional views of a sub pixel of a display device according to an exemplary embodiment of the present disclosure.

FIGS. 5A and 5B are views for explaining a method of repairing a sub pixel of a display device according to an exemplary embodiment of the present disclosure.

FIGS. 6 and 7 are cross-sectional views of a sub pixel of a display device according to another exemplary embodiment of the present disclosure.

FIGS. 8 and 9 are cross-sectional views of sub pixels of a display device according to still another exemplary embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to the drawings.

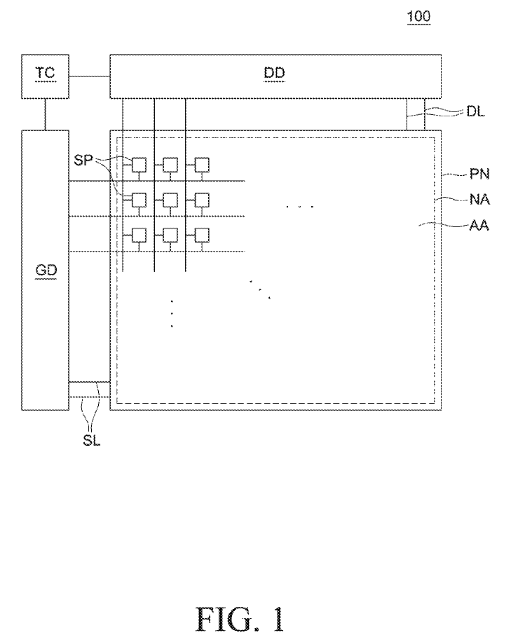

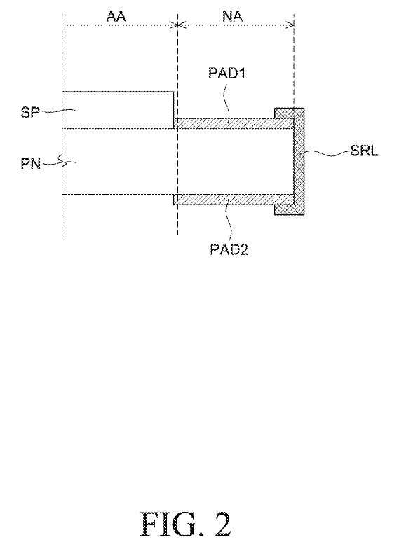

FIG. 1 is a schematic block diagram of a display device according to an exemplary embodiment of the present disclosure. FIG. 2 is a partial cross-sectional view of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD may convert image data into a data voltage using a reference gamma voltage and supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL may cross each other, and the plurality of sub pixels SP may be formed at intersections of the scan line SL and the data line DL.

In the display panel PN, a display area AA and a non-display area NA may be defined.

The display area AA is an area in which images are displayed in the display device 100. In the display area AA, a plurality of sub pixels SP constituting a plurality of pixels and a pixel circuit for driving the plurality of sub pixels SP may be disposed. The plurality of sub pixels SP is a minimum unit constituting the display area AA, and n sub pixels SP may form one pixel. A circuit for driving the plurality of light emitting elements 120 may be disposed in each of the plurality of sub pixels SP. The plurality of light emitting elements 120 may be differently defined depending on the type of the display panel PN. For example, when the display panel PN is an inorganic light emitting display panel PN, the light emitting element 120 may be a light emitting element (LED) or a micro light emitting element (micro LED).

In the display area AA, a plurality of signal lines for transmitting various signals to the plurality of sub pixels SP is disposed. For example, the plurality of signal lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL may extend in one direction in the display area AA and be connected to the plurality of sub pixels SP, and the plurality of data lines DL may extend in a direction different from the one direction in the display area AA and be connected to the plurality of sub pixels SP. In addition, a power line PL, a reference line, and the like may be further disposed in the display area AA, but are not limited thereto.

The non-display area NA is an area where an image is not displayed and may be defined as an area extending from the display area AA. In the non-display area NA, a link line and a pad electrode for transmitting a signal to the sub pixel SP of the display area AA, or a driving IC, such as a gate driver IC or a data driver IC, may be disposed. The non-display area NA may be located on a rear surface of the display panel PN, that is, a surface on which the sub pixels SP are not disposed or may be omitted, and is not limited as illustrated in the drawing.

Meanwhile, a driver such as a gate driver GD, a data driver DD, and a timing controller TC may be connected to the display panel PN in various ways. For example, the gate driver GD may be mounted in the non-display area NA in a gate-in-panel (GIP) manner or mounted between the plurality of sub pixels SP in the display area AA in a gate-in-display area (GIA) manner.

For example, the data driver DD and the timing controller TC may be formed on separate flexible films and printed circuit boards. Further, the display panel PN, the data driver DD, and the timing controller TC may be electrically connected by bonding the flexible film and the printed circuit board to the pad electrode formed in the non-display area NA of the display panel PN.

As another example, when the gate driver GD is mounted in the display area AA in the GIA manner, the flexible film and the printed circuit board may be bonded to the rear surface of the display panel PN and a side line SRL which connects the signal line on the front surface of the display panel PN to the pad electrode on the rear surface of the display panel PN is formed. Therefore, the non-display area NA on the front surface of the display panel PN may be minimized. Therefore, when the gate driver GD, the data driver DD, and the timing controller TC are connected to the display panel PN in the above-described manner, a zero bezel with substantially no bezel may be implemented.

In the non-display area NA of the display panel PN, a plurality of pad electrodes for transmitting various signals to the plurality of sub pixels SP is disposed. For example, a first pad electrode PAD1 for transmitting a signal to the plurality of sub pixels SP is disposed in the non-display area NA on the front surface of the display panel PN, and a second pad electrode PAD2 electrically connected to a driving component such as a flexible film and a printed circuit board is disposed in the non-display area NA on the rear surface of the display panel PN.

In this case, although not illustrated in the drawings, various signal lines connected to the plurality of sub pixels SP, for example, a scan line SL or a data line DL extend from the display area AA to the non-display area NA to be electrically connected to the first pad electrode PAD1.

Further, the side line SRL is disposed along the side surface of the display panel PN. The side line SRL may electrically connect the first pad electrode PAD1 on the front surface of the display panel PN and the second pad electrode PAD2 on the rear surface of the display panel PN. Therefore, a signal from the driving component on the rear surface of the display panel PN may be transmitted to the plurality of sub pixels SP through the second pad electrode PAD2, the side line SRL, and the first pad electrode PAD1. Accordingly, a signal transmission path is formed from the front surface to the side surface and the rear surface of the display panel PN to minimize an area of the non-display area NA on the front surface of the display panel PN.

Accordingly, the driving component is connected to the rear surface of the display panel PN using the side line SRL to reduce the area of the non-display area NA and implement the display device 100 with a minimized bezel. Further, when a plurality of display devices 100 with a minimized bezel is arranged to form a tiling display device, a seam area between the display device 100 and the display device 100 in which an image is not displayed is minimized to improve display quality.

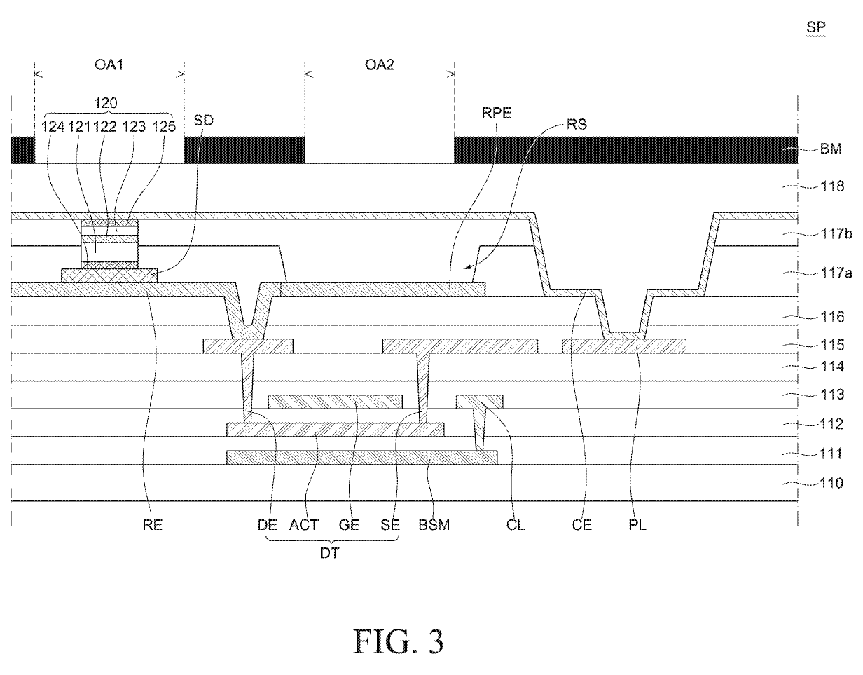

Hereinafter, a sub pixel SP of the display device 100 according to an exemplary embodiment of the present disclosure will be described in more detail with reference to FIGS. 3-6.

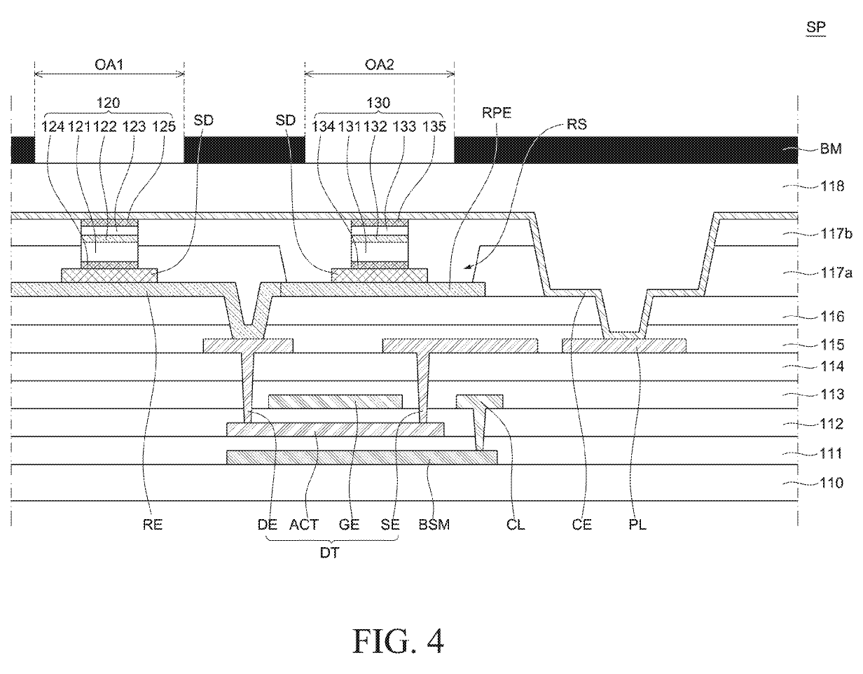

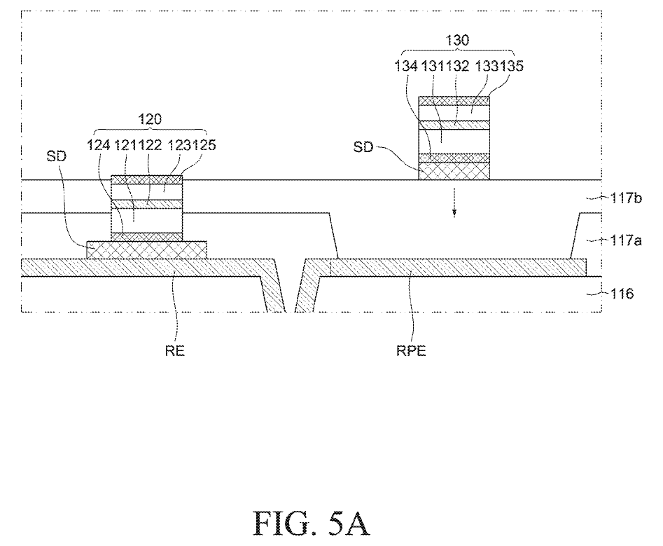

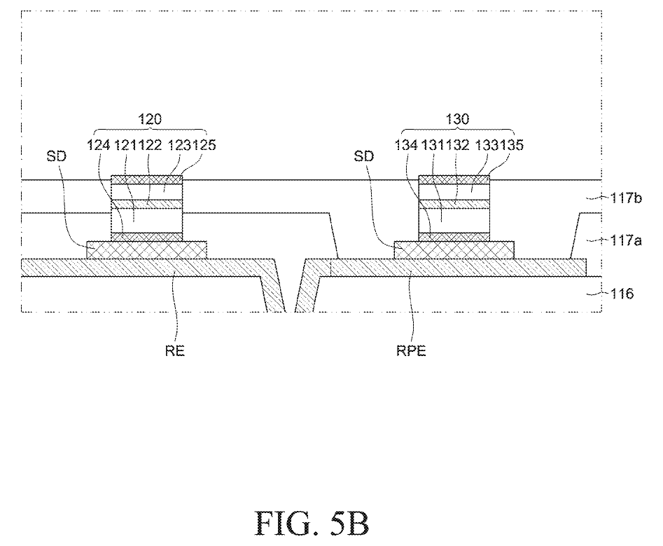

FIGS. 3 and 4 are cross-sectional views of a sub pixel of a display device according to an exemplary embodiment of the present disclosure. FIGS. 5A and 5B are views for explaining a method of repairing a sub pixel of a display device according to an exemplary embodiment of the present disclosure. Specifically, FIG. 3 is a cross-sectional view of a sub pixel SP in which a repair process has not been performed among a plurality of sub pixels SP, and FIG. 4 is a cross-sectional view of a sub pixel SP in which a repair process has been performed among a plurality of sub pixels SP.

Referring to FIGS. 1 and 3 together, the substrate 110 is a member which supports other components of the display device 100 and may be an insulating substrate 110. For example, the substrate 110 may be made of glass, resin, or the like. Further, the substrate 110 may be made of polymer, plastic, or the like, and in some embodiments, the substrate 110 may be made of a plastic material having flexibility. A plurality of sub pixels SP may be formed on the substrate 110 to display an image.

A light shielding layer BSM is disposed on the substrate 110 in each of the plurality of sub pixels SP. The light shielding layer BSM may block light incident onto the active layer ACT of the driving transistor DT to minimize a leakage current. For example, the light shielding layer BSM is disposed below the active layer ACT of the driving transistor DT to block light incident onto the active layer ACT. If light is irradiated to the active layer ACT, a leakage current is generated, which may degrade the reliability of the driving transistor DT. Accordingly, the light shielding layer BSM for blocking light is disposed on the substrate 110 to improve the reliability of the driving transistor DT. The light shielding layer BSM may be made of an opaque conductive material, such as copper (Cu), aluminum (Al), molybdenum (Mo), nickel (Ni), titanium (Ti), chromium (Cr), or an alloy thereof, but is not limited thereto.

The buffer layer 111 is disposed on the substrate 110 and the light shielding layer BSM. The buffer layer 111 is disposed to cover one surface of the substrate 110 to reduce the penetration of moisture or impurities through the substrate 110. For example, the buffer layer 111 may be configured as a single layer or multilayer made of silicon oxide (SiOx) or silicon nitride (SiNx), but is not limited thereto. The buffer layer 111 may be omitted depending on the type of substrate 110 or the type of transistor, but is not limited thereto.

The driving transistor DT is disposed on the buffer layer 111 in each of the plurality of sub pixels SP. The driving transistor DT includes an active layer ACT, a gate electrode GE, a source electrode SE, and a drain electrode DE. Meanwhile, although not illustrated in the drawings, other components, such as a switching transistor, a sensing transistor, an emission control transistor, and a storage capacitor, may be additionally disposed in each of the plurality of sub pixels SP, in addition to the driving transistor DT.

The active layer ACT of the driving transistor DT is disposed on the buffer layer 111. The active layer ACT may be disposed to overlap the light shielding layer BSM. The active layer ACT may be formed of a semiconductor material such as an oxide semiconductor, amorphous silicon, or polysilicon, but is not limited thereto. Further, although not illustrated in the drawings, active layers ACT of other transistors, such as a switching transistor, a sensing transistor, and an emission control transistor, may also be formed of a semiconductor material, such as an oxide semiconductor, amorphous silicon, or polysilicon, but are not limited thereto. In addition, the active layers ACT of the driving transistor DT, the switching transistor, the sensing transistor, and the emission control transistor may be formed of the same material or different materials.

The gate insulating layer 112 is disposed on the active layer ACT. The gate insulating layer 112 is an insulating layer which insulates the active layer ACT from the gate electrode GE. For example, the gate insulating layer 112 may be configured by a single layer or a double layer of silicon oxide (SiOx) or silicon nitride (SiNx), but is not limited thereto. In this case, even though in the drawing, it is illustrated that the gate insulating layer 112 is disposed only below the gate electrode GE, the gate insulating layer 112 may be disposed on the entire surface of the substrate 110, but is not limited thereto.

The gate electrode GE is disposed on the gate insulating layer 112. The gate electrode GE may be disposed to overlap the active layer ACT. The gate electrode GE may be configured by a conductive material such as copper (Cu), aluminum (Al), molybdenum (Mo), nickel (Ni), titanium (Ti), chromium (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, a contact hole through which the source electrode SE and the drain electrode DE are connected to the active layer ACT is formed. The first interlayer insulating layer 113 and the second interlayer insulating layer 114 are insulating layers which protect components therebelow and may be configured by a single layer or a double layer of silicon oxide (SiOx) or silicon nitride (SiNx), but are not limited thereto.

The source electrode SE and the drain electrode DE are disposed on the second interlayer insulating layer 114. The source electrode SE and the drain electrode DE may be electrically connected to the active layer ACT through contact holes formed in the first interlayer insulating layer 113, the second interlayer insulating layer 114, and the gate insulating layer 112. Any one of the source electrode SE and the drain electrode DE may be electrically connected to the light emitting element 120. For example, any one of the source electrode SE and the drain electrode DE may supply a driving current to the light emitting element 120 through the first reflective electrode RE. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

The conductive layer CL is disposed on the gate insulating layer 112. The conductive layer CL is an electrode for applying a constant voltage to the light shielding layer BSM and may be electrically connected to the light shielding layer BSM through contact holes of the gate insulating layer 112 and the buffer layer 111. For example, the light shielding layer BSM is connected to the conductive layer CL so as not to operate as a floating gate and the threshold voltage fluctuation of the driving transistor DT due to the floated light shielding layer BSM may be prevented. The conductive layer CL may be made of a conductive material, for example, copper (Cu), aluminum (Al), molybdenum (Mo), nickel (Ni), titanium (Ti), chromium (Cr), or an alloy thereof, but is not limited thereto.

The power line PL is disposed on the second interlayer insulating layer 114. The power line PL may be configured to transmit a power voltage to the light emitting element 120 of the plurality of sub pixels SP. The power line PL may be made of a conductive material, for example, copper (Cu), aluminum (Al), molybdenum (Mo), nickel (Ni), titanium (Ti), chromium (Cr), or an alloy thereof, but is not limited thereto. The power line PL may be electrically connected to the plurality of light emitting elements 120 through the second reflective electrode RE. The power line PL may be configured as either a low potential power line PL or a high potential power line PL depending on the configuration of the pixel circuit.

The passivation layer 115 is disposed on the driving transistor DT, the power line PL, and the second interlayer insulating layer 114. The passivation layer 115 is an insulating layer which protects components below the passivation layer 115. For example, the passivation layer 115 may be configured as a single layer or multilayer made of silicon oxide (SiOx) or silicon nitride (SiNx), but is not limited thereto.

The planarization layer 116 is disposed on the passivation layer 115. The planarization layer 116 may planarize an upper portion of the pixel circuit including the driving transistor DT. The planarization layer 116 may be configured as a single layer or multilayer and made of benzocyclobutene or an acrylic-based organic material, for example. However, the present disclosure is not limited thereto.

The reflective electrode RE is disposed on the planarization layer 116 in each of the plurality of sub pixels SP. The reflective electrode RE is an electrode which reflects light emitted from the light emitting element 120 toward the upper side of the substrate 110 and electrically connects the light emitting element 120 and the driving transistor DT. The reflective electrode RE may be a reflective plate that reflects light, which is directed toward the substrate 110, among light from the light emitting element 120, toward the upper side of the light emitting element 120. Further, the reflective electrode RE may be an electrode for electrically connecting the driving transistor DT and the light emitting element 120 to each other.

The reflective electrode RE may include various conductive layers in consideration of light reflection efficiency and resistance. For example, the reflective electrode RE may include a transparent conductive layer such as indium tin oxide (ITO) in an opaque conductive layer such as silver (Ag), aluminum (Al), or an alloy thereof, but the configuration of the first reflective electrode RE is not limited thereto.

The repair electrode RPE is disposed at the repair site RS of each of the plurality of sub pixels SP. The repair electrode RPE is an electrode for electrically connecting the additional light emitting element 130 and the driving transistor DT. The repair electrode RPE may be disposed on the planarization layer 116. The repair electrode RPE may extend from the reflective electrode RE and may be integrally formed with the reflective electrode RE.

The light emitting element 120 is disposed on the reflective electrode RE in each of the plurality of sub pixels SP. The light emitting element 120 is an inorganic light emitting element 120 that emits light by a driving current. The light emitting element 120 may be a light emitting diode (LED) or a micro light emitting diode (micro LED), but the exemplary embodiments of the present disclosure are not limited thereto.

The light emitting element 120 includes a first semiconductor layer 121, an emission layer 122, a second semiconductor layer 123, a first electrode 124, and a second electrode 125.

The first semiconductor layer 121 is disposed on the reflective electrode RE, and the second semiconductor layer 123 is disposed on the first semiconductor layer 121. The first semiconductor layer 121 and the second semiconductor layer 123 may be semiconductor layers doped with p-type and n-type impurities. For example, the first semiconductor layer 121 and the second semiconductor layer 123 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium(Ge), tin (Sn), and the like, but not limited thereto.

The emission layer 122 is disposed between the first semiconductor layer 121 and the second semiconductor layer 123. The emission layer 122 may emit light based on a driving current supplied to the light emitting element 120. For example, the emission layer 122 may have a single layer or a multi-quantum well (MQW) structure. For example, the emission layer 122 may be formed of indium gallium nitride (InGaN) or gallium nitride (GaN), but is not limited thereto.

The first electrode 124 is disposed below the first semiconductor layer 121. The first electrode 124 may be in contact with a lower surface of the first semiconductor layer 121. The first electrode 124 is an electrode for electrically connecting the light emitting element 120 to the reflective electrode RE and the driving transistor DT. The light emitting element 120 may be electrically connected to the driving transistor DT through the first electrode 124 and the reflective electrode RE. The first electrode 124 may be formed of an opaque conductive material, such as titanium (Ti), gold (Au), silver (Ag), copper (Cu), or an alloy thereof, a transparent conductive material, such as indium tin oxide (ITO) or indium zinc oxide (IZO), or a combination of the opaque conductive material and the transparent conductive material, but is not limited thereto.

The second electrode 125 is disposed on the second semiconductor layer 123. The second electrode 125 may be in contact with an upper surface of the second semiconductor layer 123. The second electrode 125 is an electrode for electrically connecting the light emitting element 120 to the power line PL. The light emitting element 120 may be electrically connected to the power line PL through the second electrode 125 and the common electrode CE. The second electrode 125 may be made of a transparent conductive material such as indium tin oxide (ITO) or indium zinc oxide (IZO), but is not limited thereto.

Meanwhile, although not illustrated in the drawings, a protective layer may be disposed to surround the first semiconductor layer 121, the emission layer 122, and the second semiconductor layer 123. The protective layer may protect the first semiconductor layer 121, the emission layer 122, and the second semiconductor layer 123. For example, the protective layer may be formed of an insulating material such as silicon oxide (SiOx) or silicon nitride (SiNx), but is not limited thereto.

A solder pattern SD is disposed between the light emitting element 120 and the reflective electrode RE. The solder pattern SD may connect the light emitting element 120 and the reflective electrode RE. After the light emitting element 120 having the solder pattern SD formed therebelow is positioned on the top surface of the reflective electrode RE, the temperature is raised to melt the solder pattern SD so that the light emitting element 120 may be bonded to the reflective electrode RE. The solder pattern SD may be reflowed during the melting process and spread around the light emitting element 120. For example, the solder pattern SD may be made of indium (In), tin (Sn), or an alloy thereof, but is not limited thereto.

The first insulating layer 117a is disposed on the reflective electrode RE. The first insulating layer 117a may be formed on the front surface of the substrate 110 to fix the light emitting element 120 disposed on the first insulating layer 117a. The first insulating layer 117a may be disposed to cover the lower portion of the light emitting element 120 and the solder pattern SD. The first insulating layer 117a may be disposed to surround at least a portion of the first electrode 124 and the first semiconductor layer 121 of the configuration of the light emitting element 120, and may not be disposed on the repair electrode RPE. For example, the first insulating layer 117a may be configured by any one of adhesive polymer, epoxy resist, UV resin, polyimide series, acrylate series, urethane series, and polydimethylsiloxane (PDMS), but is not limited thereto.

The first insulating layer 117a may temporarily fix the light emitting element 120 during a soldering process of melting and bonding the solder pattern SD. For example, after coating the entire surface of the substrate 110 with a material of the first insulating layer 117a, the first insulating layer 117a may be temporarily cured. Subsequently, after the light emitting element 120 formed on the solder pattern SD is transferred onto the first insulating layer 117a, the flowability of the first insulating layer 117a may increase when the temperature is raised. For example, when the temperature of the first insulating layer 117a is increased to 200 degrees, the fluidity of the first insulating layer 117a is increased so that the light emitting element 120 may settle below the first insulating layer 117a. The light emitting element 120 and the solder pattern SD may descend into the first insulating layer 117a having increased fluidity and may be disposed on the top surface of the reflective electrode RE. That is, the light emitting element 120 and the solder pattern SD may settle below the first insulating layer 117a. To this end, the first insulating layer 117a may be formed of an organic material whose fluidity increases between 100 degrees and 200 degrees.

Further, the temperature may be further increased to melt the solder pattern SD. For example, the temperature may be raised to about 210 degrees to 260 degrees to melt the solder pattern SD. The reflowed solder pattern SD spreads around the light emitting element 120 and may connect the light emitting element 120 and the reflective electrode RE to each other. At this time, pressure is applied during the soldering process to more stably connect the light emitting element 120 to the reflective electrode RE.

Finally, the first insulating layer 117a may be cured to fix the light emitting element 120. Accordingly, the light emitting element 120 transferred onto the first insulating layer 117a may be electrically connected to the reflective electrode RE below the first insulating layer 117a through a stepwise temperature increase, and the light emitting element 120 may be fixed to the first insulating layer 117a.

The second insulating layer 117b is disposed on the first insulating layer 117a and the light emitting element 120. The second insulating layer 117b may be formed on the entire surface of the substrate 110 to fix the light emitting element 120. The second insulating layer 117b may be disposed to cover a part of a side surface and an upper side of the light emitting element 120. The second insulating layer 117b may be disposed to surround at least a portion of the second semiconductor layer 123 of the configuration of the light emitting element 120. However, in order to connect the light emitting element 120 and the common electrode CE, at least a portion of the second electrode 125 may be exposed from the second insulating layer 117b. For example, the second insulating layer 117b may be configured by any one of adhesive polymer, epoxy resist, UV resin, polyimide series, acrylate series, urethane series, and polydimethylsiloxane (PDMS), but is not limited thereto.

Further, each of the first insulating layer 117a and the second insulating layer 117b temporarily fixing the light emitting element 120 and the additional light emitting element 130 before the soldering process may also be referred to as a first adhesive layer and a second adhesive layer.

Next, the common electrode CE is disposed on the second insulating layer 117b. The common electrode CE is an electrode for electrically connecting the light emitting element 120 and the power line PL. The common electrode CE may be electrically connected to the power line PL through contact holes of the first insulating layer 117a, the second insulating layer 117b, the planarization layer 116, and the passivation layer 115. The common electrode CE may be electrically connected to the second electrode 125 of the light emitting element 120 exposed from the second insulating layer 117b.

A protective layer 118 is disposed on the common electrode CE. The protective layer 118 may protect the configuration below the protective layer 118. Further, the protective layer 118 may provide a flat surface on the common electrode CE. The protective layer 118 may be formed of either an organic insulating material or an inorganic insulating material.

The black matrix BM is disposed on the protective layer 118. The black matrix BM may shield light of each of the plurality of sub pixels SP so as not to be mixed with each other. In addition, the black matrix BM absorbs light incident from the outside to the display device 100, thereby minimizing a decrease in visibility due to the reflection of external light from the configuration inside the display device 100. For example, the black matrix BM includes a black component and may be formed of an organic material such as an opaque resin including a pigment, but is not limited thereto.

The black matrix BM includes a first opening OA1 and a second opening OA2 overlapping each of the plurality of sub pixels SP. The first opening OA1 may overlap the light emitting element 120. Light from the light emitting element 120 may propagate toward the outside of the display device 100 through the first opening OA1. The second opening OA2 may overlap the repair site RS. Each of the plurality of sub pixels SP may include a repair site RS. When the defective sub pixel SP is repaired, the additional light emitting element 130 may be transferred to the defective sub pixel SP, and the repair site RS is an area in which the additional light emitting element 130 is disposed.

Referring to FIG. 4, in some of the plurality of sub pixels SP where the repair process has been performed, the additional light emitting element 130 is disposed on the repair electrode RPE. The additional light emitting element 130 may be disposed on the repair electrode RPE of the repair site RS.

Like the light emitting element 120, the additional light emitting element 130 may be either a light emitting diode (LED) or a micro light emitting diode (micro LED).

The additional light emitting element 130 includes a first additional semiconductor layer 131, an additional emission layer 132, a second additional semiconductor layer 133, a first additional electrode 134, and a second additional electrode 135. Each of the first additional semiconductor layer 131, the additional emission layer 132, the second additional semiconductor layer 133, the first additional electrode 134, and the second additional electrode 135 of the additional light emitting element 130 may be substantially the same as the first semiconductor layer 121, the emission layer 122, the second semiconductor layer 123, the first electrode 124, and the second electrode 125 of the light emitting element 120.

A solder pattern SD is disposed between the additional light emitting element 130 and the repair electrode RPE. The solder pattern SD may connect the additional light emitting element 130 and the repair electrode RPE. After the additional light emitting element 130 with the solder pattern SD formed therebelow is transferred to the repair site RS, the temperature is raised to melt the solder pattern SD so that the additional light emitting element 130 may be bonded to the repair electrode RPE.

Referring to FIGS. 5A and 5B, after detecting a defective sub pixel SP among the plurality of sub pixels SP, the additional light emitting element 130 is transferred to repair the defective sub pixel SP.

First, after the light emitting element 120 is transferred, a defective sub pixel SP may be detected. For example, a defective sub pixel SP in which a non-transfer failure of the light emitting element 120 or an alignment error of the light emitting element 120 occurs may be detected.

Referring to FIG. 5A, after detecting the defective sub pixel SP, the additional light emitting element 130 having the solder pattern SD may be transferred on the second insulating layer 117b in the temporary curing state. At this time, the first insulating layer 117a which temporarily fixes the light emitting element 120 is cured in the curing process of the first insulating layer 117a so that the additional light emitting element 130 cannot settle therein. Therefore, when the first insulating layer 117a is formed, the first insulating layer 117a may be patterned so as not to be disposed on the repair electrode RPE located at the repair site RS, or a part of the first insulating layer 117a overlapping the repair site RS may be removed before the second insulating layer 117b is formed. Accordingly, the second insulating layer 117b may be covering and contacting the repair electrode RPE located at the repair site RS.

Referring to FIG. 5B together, after transferring the additional light emitting element 130 onto the second insulating layer 117b, the temperature of the second insulating layer 117b is increased to increase the fluidity of the second insulating layer 117b. Accordingly, the solder pattern SD and the additional light emitting element 130 may be lowered into the second insulating layer 117b and disposed on the top surface of the repair electrode RPE. Further, the additional light emitting element 130 may be coupled to the repair electrode RPE by melting and reflowing the solder pattern SD through a soldering process. In this case, pressure is applied to the additional light emitting element 130 in the soldering process to more firmly connect the additional light emitting element 130 to the repair electrode RPE. To this end, the second insulating layer 117b may be formed of an organic material whose fluidity increases between 100 degrees and 200 degrees. The second insulating layer 117b may be formed of the same material as the first insulating layer 117a, but is not limited thereto.

Finally, the second insulating layer 117b may be cured to fix and protect the additional light emitting element 130. Accordingly, by increasing the fluidity of the second insulating layer 117b and allowing the additional light emitting element 130 to settled below the second insulating layer 117b, the additional light emitting element 130 may be connected to the repair electrode RPE.

Accordingly, in the display device 100 according to the exemplary embodiment of the present disclosure, a repair site RS through which the additional light emitting element 130 may be transferred is formed in each of the plurality of sub pixels SP to minimize the defective sub pixel SP. The repair electrode RPE may be formed at the repair site RS to electrically connect the additional light emitting element 130 and the driving transistor DT to each other. Further, a second opening OA2 overlapping the repair site RS is formed in the black matrix BM to transmit light from the additional light emitting element 130 to the outside of the display device 100.

Further, in the display device 100 according to the exemplary embodiment of the present disclosure, in the process of increasing the temperature to perform the soldering process, the fluidity of the first insulating layer 117a and the second insulating layer 117b may be improved. By doing this, the light emitting element 120 may be moved to the reflective electrode RE and the additional light emitting element 130 may be moved to the repair electrode RPE. That is, the soldering process and the transfer of the light emitting element 120 may be performed simultaneously. During the process of increasing the temperature, the process of placing the light emitting element 120 on the reflective electrode RE and the repair process may be performed together, so that a separate process is not required and the structure of the display device 100 may be simplified. In addition, since the soldering process is performed in a state in which the light emitting element 120 is fixed to the first insulating layer 117a and the additional light emitting element 130 is fixed to the second insulating layer 117b, the connection failure may be minimized. Accordingly, the light emitting element 120 and the additional light emitting element 130 may be directly connected to each of the reflective electrode RE and the repair electrode RPE below the first insulating layer 117a, thereby simplifying the connection structure of the light emitting element 120 and the additional light emitting element 130 and the reflective electrode RE and the repair electrode RPE.

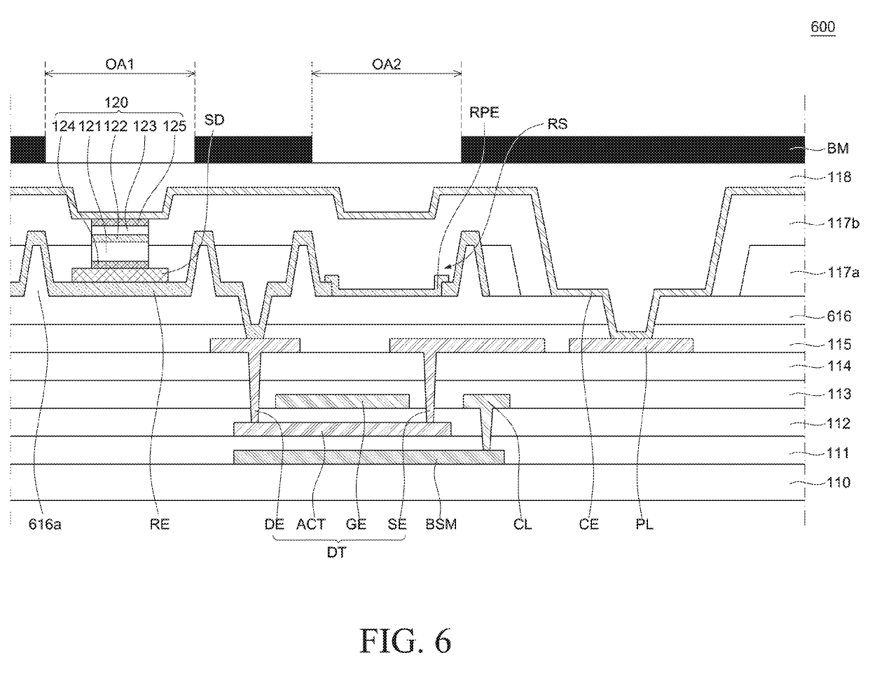

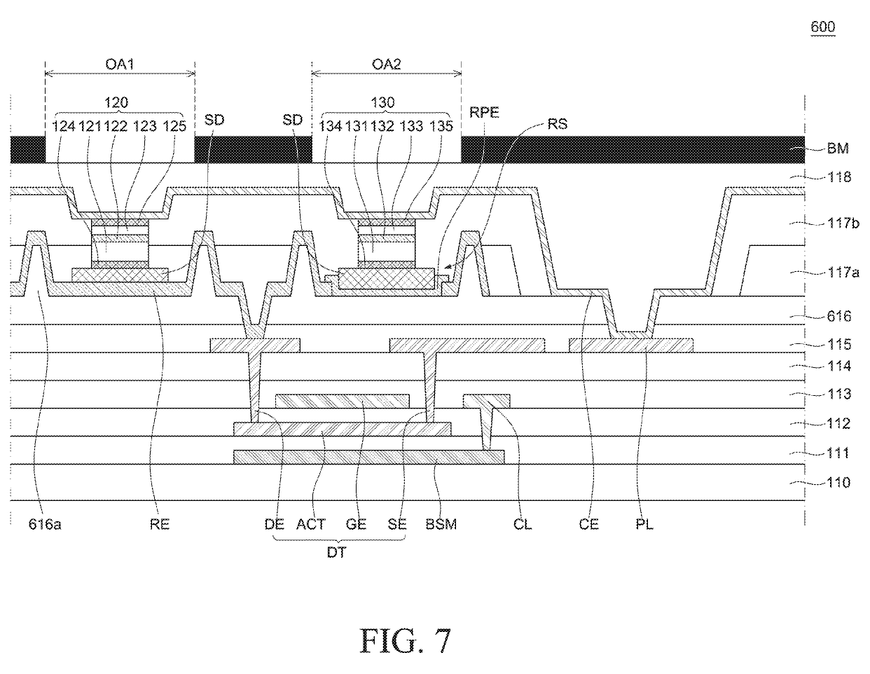

FIGS. 6 and 7 are cross-sectional views of a sub pixel of a display device according to another exemplary embodiment of the present disclosure. Specifically, FIG. 6 is a cross-sectional view of a sub pixel SP in which a repair process has not been performed among a plurality of sub pixels SP, and FIG. 7 is a cross-sectional view of a sub pixel SP in which a repair process has been performed among a plurality of sub pixels SP. A display device 600 in FIGS. 6 and 7 is substantially identical in configuration to the display device 100 in FIGS. 1 to 5B, except for the configuration of the protruding portion 616a and the repair electrode RPE of the second planarization layer 616. Therefore, repeated descriptions of the identical components will be omitted.

Referring to FIG. 6, the second planarization layer 616 includes a plurality of protrusions 616a. The plurality of protrusions 616a is portions protruding from the top surface of the second planarization layer 616. The plurality of protrusions 616a may be disposed to overlap edges of the first opening OA1 and the second opening OA2 of the black matrix BM. The plurality of protrusions 616a may be disposed to surround the area in which the light emitting element 120 is disposed and the repair site RS.

The reflective electrode RE may be disposed on the second planarization layer 616 including a plurality of protrusions 616a. A part of the reflective electrode RE, which covers the plurality of protrusions 616a, may be located on the side portion of the light emitting element 120 and reflect light, which is directed in the lateral direction, toward the upper side of the substrate 110. The reflective electrode RE may be disposed along a top surface of the second planarization layer 616 on which the plurality of protrusions 616a is formed, and may be formed in a cup shape surrounding a lower portion and a side portion of the light emitting element 120. In addition, the reflective electrode RE may be formed in a cup shape surrounding a side portion of the repair site RS. The reflective electrode RE may include a cup-shaped portion which encloses an area of the first opening OA1 in which the light emitting element 120 is disposed and a cup-shaped portion which encloses an area of the second opening OA2 in which the repair site RS is formed.

At the repair site RS, the repair electrode RPE is disposed on the second planarization layer 616 and the reflective electrode RE. A portion of the reflective electrode RE overlapping the repair site RS is patterned, and the repair electrode RPE is disposed on the patterned portion. The repair electrode RPE may be disposed in a portion where the reflective electrode RE is patterned, and may cover an edge of the reflective electrode RE. The repair electrode RPE may be electrically connected to the reflective electrode RE. Accordingly, the additional light emitting element 130 transferred onto the repair electrode RPE may receive a signal from the driving transistor DT through the repair electrode RPE and the reflective electrode RE.

The repair electrode RPE may be made of a conductive material having a low reflectance. For example, the repair electrode RPE may be made of a transparent conductive material such as indium tin oxide (ITO) or indium zinc oxide (IZO), but is not limited thereto.

In the meantime, when the reflective electrode RE is not patterned, in the normal sub pixel SP in which the additional light emitting element 130 is not disposed, the reflective electrode RE is exposed from the second opening OA2, and external light is reflected by the reflective electrode RE to degrade visibility. Therefore, in the area overlapping the second opening OA2, the reflective electrode RE is patterned, and only the repair electrode RPE having a reflectance lower than that of the reflective electrode RE is disposed to minimize the reflection of external light.

Next, the first insulating layer 117a is disposed on the reflective electrode RE. The first insulating layer 117a may be disposed in an area other than the repair site RS. The repair electrode RPE may be exposed from the first insulating layer 117a.

A part of the second insulating layer 117b overlapping the first opening OA1 and the second opening OA2 is partially patterned so that the second electrode 125 of the light emitting element 120 and the second additional electrode 135 of the additional light emitting element 130 may be exposed from the second insulating layer 117b. Therefore, the second insulating layer 117b is patterned so that the light emitting element 120 and the additional light emitting element 130 are exposed from the second insulating layer 117b to electrically connect the common electrode CE, the light emitting element 120, and the additional light emitting element 130.

Referring to FIG. 7, the additional light emitting element 130 may be transferred to the defective sub pixel SP to repair the defective sub pixel SP. Specifically, after the second insulating layer 117b in the temporary curing state is formed, the additional light emitting element 130 in which the solder pattern SD is formed on the lower portion may be transferred onto the second insulating layer 117b. In this case, by increasing the temperature of the second insulating layer 117b to increase the fluidity of the second insulating layer 117b, the additional light emitting element 130 may be lowered toward the repair electrode RPE below the second insulating layer 117b. Finally, the repair electrode RPE and the additional light emitting element 130 may be electrically connected through a soldering process of the solder pattern SD.

Meanwhile, at the repair site RS, a repair electrode RPE made of a material having a low reflectance is disposed under the additional light emitting element 130 instead of the reflective electrode RE. In this case, the solder pattern SD made of an opaque conductive material functions like the reflective electrode RE to reflect the light of the additional light emitting element 130 to the upper portion of the substrate 110. Accordingly, in the sub pixel SP in which the additional light emitting element 130 is not disposed, only the repair electrode RPE is disposed to reduce the reflection of external light, and in the sub pixel SP in which the additional light emitting element 130 is disposed, the solder pattern SD is disposed to reflect the light of the additional light emitting element 130 toward the upper side of the additional light emitting element 130.

Accordingly, in the display device 600 according to another exemplary embodiment of the present disclosure, the plurality of protrusions 616a is disposed on the top surface of the second planarization layer 616 to form the cup-shaped reflective electrode RE, thereby improving the light extraction efficiency. The reflective electrode RE may be disposed along a surface of the second planarization layer 616 and may be configured in a cup shape surrounding areas of the first opening OA1 and the second opening OA2. Accordingly, among light emitted from the light emitting element 120 and the additional light emitting element 130, light directed in the lateral direction may be reflected toward the outside of the display device 600 by the reflective electrode RE. Accordingly, the light extraction efficiency and luminance of the display device 600 may be improved by the reflective electrode RE.

In the display device 600 according to another exemplary embodiment of the present disclosure, the reflective electrode RE overlapping the repair site RS is patterned and only the repair electrode RPE having a reflectance lower than that of the reflective electrode RE is formed to minimize the reflection of external light. At the repair site RS overlapping the second opening OA2 of the black matrix BM, the repair electrode RPE made of a material having a low reflectance may be disposed instead of the reflective electrode RE. Further, in some sub pixels SP in which the additional light emitting element 130 is disposed, the solder pattern SD functions as a reflector like the reflective electrode RE to increase the light extraction efficiency of the additional light emitting element 130.

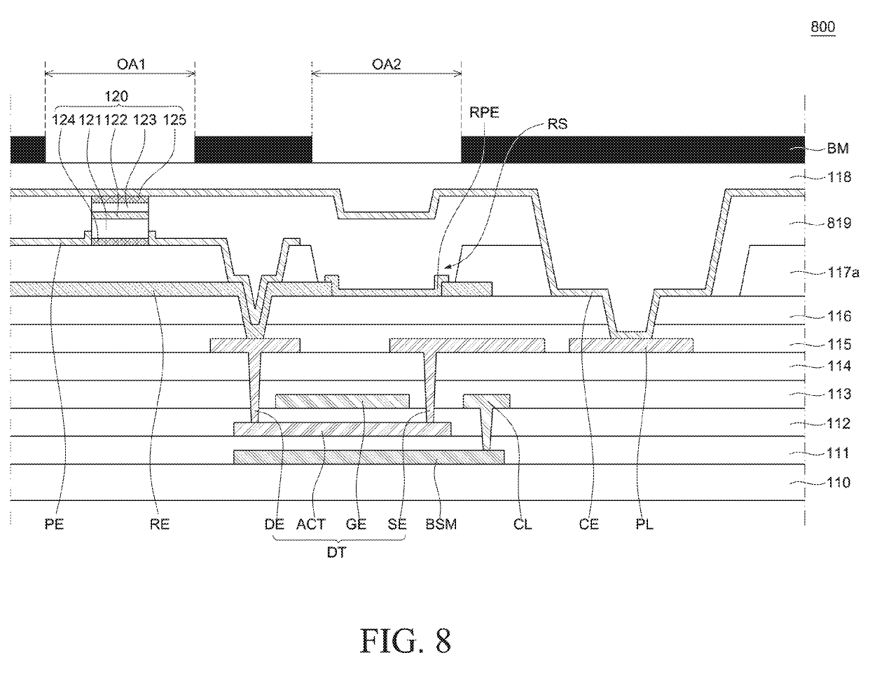

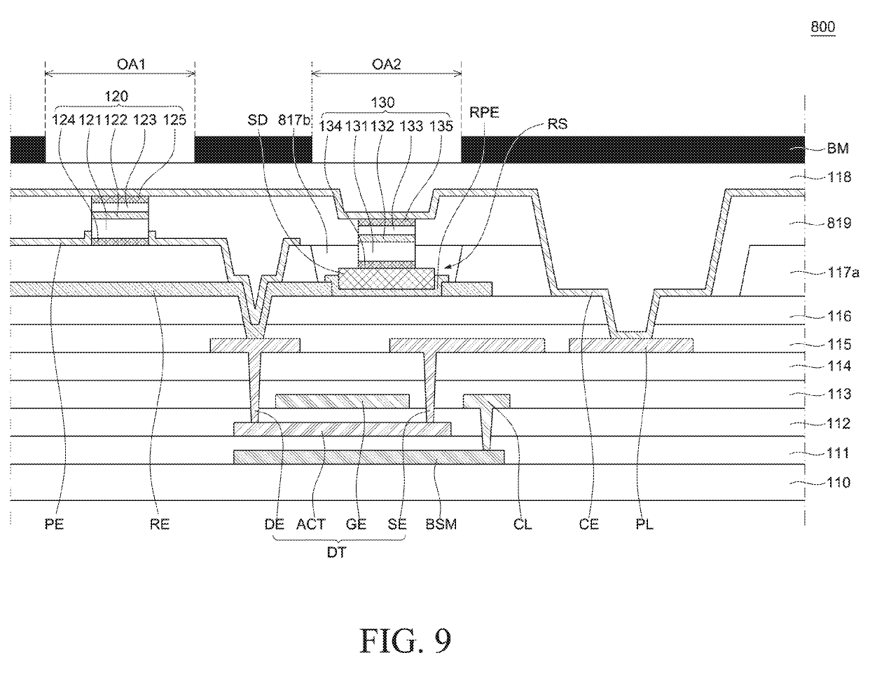

FIGS. 8 and 9 are cross-sectional views of sub pixels of a display device according to still another exemplary embodiment of the present disclosure. Specifically, FIG. 8 is a cross-sectional view of a sub pixel SP in which a repair process has not been performed among a plurality of sub pixels SP, and FIG. 9 is a cross-sectional view of a sub pixel SP in which a repair process has been performed among a plurality of sub pixels SP. A display device 800 of FIGS. 8 and 9 further includes a configuration of a third insulating layer 819, a pixel electrode PE, and a repair electrode RPE compared to the display device 100 of FIGS. 1-5B, only positions of the light emitting element 120 and the second insulating layer 817b are different, but other configurations are substantially the same, so that a redundant description will be omitted.

Referring to FIG. 8, the light emitting element 120 is disposed on the first insulating layer 117a. The light emitting element 120 may be disposed on the top surface of the first insulating layer 117a. In this case, the first insulating layer 117a may function as an adhesive layer that temporarily fixes the light emitting element 120 when connecting the light emitting element 120 and the pixel electrode PE.

The pixel electrode PE is disposed on the first insulating layer 117a. The pixel electrode PE is an electrode which electrically connects the light emitting element 120 and the reflective electrode RE. The pixel electrode PE may be in contact with the side surface of the light emitting element 120. The pixel electrode PE may be in contact with the first electrode 124 at the lower part of the light emitting element 120 and the side surface of the first semiconductor layer 121. Further, the pixel electrode PE may be electrically connected to the reflective electrode RE through a contact hole of the first insulating layer 117a. Accordingly, the first electrode 124 and the reflective electrode RE of the light emitting element 120 may be electrically connected to each other through the pixel electrode PE.

The repair electrode RPE is disposed at the repair site RS. A portion of the reflective electrode RE overlapping the repair site RS is patterned, and the repair electrode RPE may be formed in the patterned portion. The repair electrode RPE may cover at least a portion of the reflective electrode RE.

The repair electrode RPE is made of a conductive material having a reflectance lower than that of the reflective electrode RE to minimize reflection of external light. For example, the repair electrode RPE may be formed of a multilayer low reflection electrode RE. For example, the repair electrode RPE may include at least one of a transparent conductive material and a low reflectance conductive material. For example, the repair electrode RPE may have a multi-layered structure of indium tin oxide (ITO), molybdenum titanium alloy (Mo Ti), and copper (Cu).

In this case, the repair electrode RPE may be exposed from the first insulating layer 117a. During the repair process of the sub pixel SP, the first insulating layer 117a covering the repair electrode RPE may be removed so that the additional light emitting element 130 may be disposed on the top surface of the repair electrode RPE.

The third insulating layer 819 is disposed on the first insulating layer 117a. The third insulating layer 819 may be disposed to cover the light emitting element 120, the pixel electrode PE, and the repair electrode RPE. At least the second electrode 125 in the configuration of the light emitting element 120 may be exposed from the third insulating layer 819. The third insulating layer 819 is an insulating layer for fixing and protecting the light emitting element 120 and the additional light emitting element 130. For example, the third insulating layer 819 may be formed of an acrylic organic material, but is not limited thereto.

The common electrode CE is disposed on the third insulating layer 819. The common electrode CE may be connected to the second electrode 125 of the light emitting element 120 exposed from the third insulating layer 819. Further, the common electrode CE may be connected to the power line PL through contact holes of the third insulating layer 819, the first insulating layer 117a, and the planarization layer 116. Accordingly, the light emitting element 120 may be electrically connected to the power line PL through the common electrode CE.

Referring to FIG. 9, the second insulating layer 817b may be disposed only at the repair site RS of the sub pixel SP on which the repair process has been performed. That is, the second insulating layer 817b may not be disposed in some sub pixels SP in which the additional light emitting element 130 is not disposed among the plurality of sub pixels SP, and the second insulating layer 817b may be disposed in some other sub pixels SP in which the additional light emitting element 130 is disposed.

A second insulating layer 817b may be disposed in a space between the first insulating layers 117a at the repair site RS. The second insulating layer 817b may cover the repair electrode RPE exposed from the first insulating layer 117a. The second insulating layer 817b may be disposed to surround the solder pattern SD and the additional light emitting element 130.

The repair process may be performed first before forming the third insulating layer 819 on the entire surface of the substrate 110. During the repair process, the second insulating layer 817b may be formed on the repair site RS exposed from the first insulating layer 117a. The additional light emitting element 130 having the solder pattern SD may be transferred onto the second insulating layer 817b in the temporary curing state. By increasing the temperature, the fluidity of the second insulating layer 817b may be increased, and the solder pattern SD and the additional light emitting element 130 may be moved onto the repair electrode RPE. Next, by further increasing the temperature to melt the solder pattern SD, the additional light emitting element 130 may be connected to the repair electrode RPE.

After the repair is completed, the third insulating layer 819 may be formed on the entire surface of the substrate 110 to cover the light emitting element 120 and the additional light emitting element 130. In this case, since the additional light emitting element 130 is disposed at a lower height than the light emitting element 120, a part of the third insulating layer 819 covering the upper portion of the additional light emitting element 130 may be patterned to expose the second additional electrode 135 of the additional light emitting element 130 from the third insulating layer 819. Accordingly, the common electrode CE formed on the third insulating layer 819 may also be connected to the additional light emitting element 130.

Accordingly, in the display device 800 according to still another exemplary embodiment of the present disclosure, the repair electrode RPE having a low reflective is formed at the repair site RS to reduce the reflection of external light. The repair electrode RPE made of a low-reflective material is disposed at the repair site RS overlapping the second opening OA2 of the black matrix BM to minimize reflection of external light in the sub pixel SP where the additional light emitting element 130 is not disposed.

The exemplary embodiments of the present disclosure can also be described as follows:

A display device according to an exemplary embodiment of the present disclosure includes a substrate in which a plurality of sub pixels each including a repair site is defined, a reflective electrode disposed in each of the plurality of sub pixels, a repair electrode disposed at the repair site and electrically connected to the reflective electrode, a light emitting element disposed on the reflective electrode, a first insulating layer disposed on the reflective electrode and the repair electrode and in contact with at least a part of the light emitting element, and a second insulating layer disposed on the repair electrode in at least some of the plurality of sub pixels, the first insulating layer is opened at the repair site to expose the repair electrode from the first insulating layer, and the second insulating layer is in contact with the repair electrode.

According to another aspect of the present disclosure, the repair electrode may be integrally formed with the reflective electrode.

According to yet another aspect of the present disclosure, the repair electrode may be a transparent electrode.

According to yet another aspect of the present disclosure, the repair electrode may be made of a material having a reflectivity lower than that of the reflective electrode.

According to yet another aspect of the present disclosure, an additional light emitting element disposed on the repair electrode of some of the plurality of sub pixels, and a first solder pattern disposed between the additional light emitting element and the repair electrode may be further included.

According to yet another aspect of the present disclosure, further comprising a second solder pattern, the second solder pattern may be disposed between the light emitting element and the reflective electrode, and the first insulating layer may be disposed to cover the reflective electrode, the second solder pattern, and a part of the light emitting element.

According to yet another aspect of the present disclosure, the second insulating layer may be disposed to cover the first insulating layer, the light emitting element, and the additional light emitting element.

According to yet another aspect of the present disclosure, the display device may further comprise a pixel electrode disposed on a top surface of the first insulating layer and configured to contact a side surface of the light emitting element, wherein the light emitting element may be disposed on a top surface of the first insulating layer.

According to yet another aspect of the present disclosure, the second insulating layer may be disposed at a repair site of some sub pixels including an additional light emitting element among the plurality of sub pixels.

According to yet another aspect of the present disclosure, the display device may further include a third insulating layer disposed on the first insulating layer and the second insulating layer, and in some sub pixels including an additional light emitting element among the plurality of sub pixels, the third insulating layer may be disposed to cover the second insulating layer, and in the remaining sub pixels including no additional light emitting element among the plurality of sub pixels, the third insulating layer may be disposed to cover the repair electrode.

According to yet another aspect of the present disclosure, a black matrix which is disposed on the first insulating layer, the second insulating layer, and the light emitting element and has a first opening overlapping the light emitting element and a second opening overlapping the repair site may be further included.

According to yet another aspect of the present disclosure, a planarization layer which is disposed between the substrate and the reflective electrode and includes a plurality of protrusions may be further included, and the plurality of protrusions may overlap an edge of the first opening and an edge of the second opening.

According to yet another aspect of the present disclosure, the reflective electrode may be disposed to cover the plurality of protrusions.

According to yet another aspect of the present disclosure, the second insulating layer may be made of an organic material whose fluidity increases at a temperature of 100 degrees or more.

According to yet another aspect of the present disclosure, at the repair site, the repair electrode may be disposed on the planarization layer and the reflective electrode.

According to yet another aspect of the present disclosure, a portion of the reflective electrode overlapping with the repair site may be patterned, and the repair electrode is disposed in the patterned portion of the reflective electrode.

According to yet another aspect of the present disclosure, a part of the second insulating layer overlapping the first opening and the second opening may be partially patterned, so that a part of the light emitting element and a part of the additional light emitting element are exposed from the second insulating layer.

According to yet another aspect of the present disclosure, the additional light emitting element may be disposed at a lower height than the light emitting element.

According to yet another aspect of the present disclosure, a part of the third insulating layer may be patterned to expose a part of the additional light emitting element from the third insulating layer.

A display device according to another exemplary embodiment of the present disclosure includes: a substrate in which a plurality of sub pixels are defined, wherein at least a part of the sub pixels include a light emitting element and an additional light emitting element, wherein each of the at least a part of the sub pixels includes: a reflective electrode disposed on the substrate; a repair electrode electrically connected to the reflective electrode; the light emitting element disposed on the reflective electrode; the additional light emitting element disposed on the repair electrode; a first insulating layer disposed on the reflective electrode; and a second insulating layer disposed on the first insulating layer, and wherein the second insulating layer is in contact with the repair electrode.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure. All the technical concepts in the equivalent scope of the present disclosure should be construed as falling within the scope of the present disclosure.

What is claimed is:

1. A display device, comprising:
a substrate in which a plurality of sub pixels each including a repair site is defined;
a reflective electrode disposed in each of the plurality of sub pixels;
a repair electrode disposed at the repair site and electrically connected to the reflective electrode;
a light emitting element disposed on the reflective electrode;
a first insulating layer disposed on the reflective electrode and the repair electrode and in contact with at least a part of the light emitting element; and
a second insulating layer disposed on the repair electrode in at least some of the plurality of sub pixels,
wherein the first insulating layer is opened at the repair site to expose the repair electrode from the first insulating layer, and the second insulating layer is in contact with the repair electrode.

2. The display device according to claim 1, wherein the repair electrode is integrally formed with the reflective electrode.

3. The display device according to claim 1, wherein the repair electrode is a transparent electrode.

4. The display device according to claim 1, wherein the repair electrode is formed of a material having a reflectance lower than that of the reflective electrode.

5. The display device of claim 1, further comprising:
an additional light emitting element disposed on the repair electrode of some of the plurality of sub pixels; and
a first solder pattern disposed between the additional light emitting element and the repair electrode.

6. The display device of claim 5, further comprising a second solder pattern, wherein the second solder pattern is disposed between the light emitting element and the reflective electrode, and the first insulating layer is disposed to cover the reflective electrode, the second solder pattern, and a part of the light emitting element.

7. The display device according to claim 6, wherein the second insulating layer is disposed to cover the first insulating layer, the light emitting element, and the additional light emitting element.

8. The display device of claim 5, further comprising:
a pixel electrode disposed on a top surface of the first insulating layer and in contact with a side surface of the light emitting element,
wherein the light emitting element is disposed on a top surface of the first insulating layer.

9. The display device according to claim 8, wherein the second insulating layer is disposed at the repair site of some sub pixels including the additional light emitting element among the plurality of sub pixels.

10. The display device of claim 9, further comprising:
a third insulating layer disposed on the first insulating layer and the second insulating layer,
wherein in some sub pixels including the additional light emitting element among the plurality of sub pixels, the third insulating layer is disposed to cover the second insulating layer, and
in remaining sub pixels not including the additional light emitting element among the plurality of sub pixels, the third insulating layer is disposed to cover the repair electrode.

11. The display device according to claim 1, further comprising:
a black matrix which is disposed on the first insulating layer, the second insulating layer, and the light emitting element and has a first opening overlapping the light emitting element and a second opening overlapping the repair site.

12. The display device of claim 11, further comprising:
a planarization layer disposed between the substrate and the reflective electrode and including a plurality of protrusions,
wherein the plurality of protrusions overlaps an edge of the first opening and an edge of the second opening.

13. The display device according to claim 12, wherein the reflective electrode is disposed to cover the plurality of protrusions.

14. The display device according to claim 1, wherein the second insulating layer is formed of an organic material whose fluidity increases at a temperature of 100 degrees or more.

15. The display device according to claim 12, wherein at the repair site, the repair electrode is disposed on the planarization layer and the reflective electrode.

16. The display device according to claim 15, wherein a portion of the reflective electrode overlapping with the repair site is patterned, and the repair electrode is disposed in the patterned portion of the reflective electrode.

17. The display device according to claim 5, wherein a part of the second insulating layer overlapping the first opening and the second opening is partially patterned, so that a part of the light emitting element and a part of the additional light emitting element are exposed from the second insulating layer.

18. The display device according to claim 10, wherein the additional light emitting element is disposed at a lower height than the light emitting element.

19. The display device according to claim 18, wherein a part of the third insulating layer is patterned to expose a part of the additional light emitting element from the third insulating layer.

20. A display device, comprising:
a substrate in which a plurality of sub pixels are defined,
wherein at least a part of the sub pixels include a light emitting element and an additional light emitting element,
wherein each of the at least a part of the sub pixels includes:
a reflective electrode disposed on the substrate;
a repair electrode electrically connected to the reflective electrode;
the light emitting element disposed on the reflective electrode;
the additional light emitting element disposed on the repair electrode;
a first insulating layer disposed on the reflective electrode; and
a second insulating layer disposed on the first insulating layer, and
wherein the second insulating layer is in contact with the repair electrode.
